(19) United States
(12) Patent Application Publication
(10) Pub. No.: US 2026/0136873 A1
(43) Pub. Date: May 14, 2026

(54) SURFACE MOUNT DEVICE FOR COLORFUL CHIPS AND COLORFUL CHIPS SURFACE MOUNT METHOD

(71) Applicant: SUZHOU LUUMII LTD., Suzhou City (CN)

(72) Inventors: Yu-Kai LIN, New Taipei City (TW); Chen-Fang KANG, New Taipei City (TW)

(21) Appl. No.: 18/948,450

(22) Filed: Nov. 14, 2024

(51) Int. Cl. H01L 21/67; H01L 21/683

(52) U.S. Cl. CPC H10P 72/0446; H10P 72/0618; H10P 72/74; H10P 72/7408

(57) ABSTRACT

This disclosure is directed to a surface mount device for colorful chips. The surface mount device has a base, a first transferring mechanism, a second transferring mechanism, a frame, a color identification module and a punching mechanism. The base carries the circuit board, the first transferring mechanism is arranged on the base, and the second transferring mechanism is arranged on the first transferring mechanism. The frame carries the transparent film. The frame is arranged on the first transferring mechanism and above the base. The frame has a window, and a side of the transparent film carrying the colored crystal grains faces to the circuit board. The color identification module is aligned to an area defined in the window. The color identification module is suspended on the frame. The punching mechanism is arranged on the second transferring mechanism and suspended over the window.

### BACKGROUND OF THE INVENTION

### Technical Field

This disclosure is directed to a surface mount device for chips, in particular to a surface mount device for colorful chips.

### Description of Related Art

A light-emitting keyboard of related art has a circuit board, in general. On the circuit board, keys are provided, and light-emitting diode chips are disposed corresponding to the keys respectively. According to a surface mounting method of related art, the chips are respectively picked and mounted to arrangement points on the circuit board by a robotic arm, the operation is inefficiently. Moreover, the aforementioned device has a complex mechanism so that the mechanism is therefore difficult to be positioned and errors may occur in the operation, and this may lead to a poor yield. Furthermore, a cost of arranging the robotic arm is quite expensive.

In views of this, in order to solve the above disadvantage, the inventor studied related technology and provided a reasonable and effective solution in this disclosure.

### SUMMARY OF THE INVENTION

This disclosure is directed to a surface mount device for colorful chips which is used for mounting a plurality of colorful chips carried on a transparent film on to a circuit board. The surface mount device for colorful chips has a base, a first transferring mechanism, a second transferring mechanism, a frame, a color identification module and a punching mechanism. The base is used for carrying the circuit board, the first transferring mechanism is arranged on the base, and the second transferring mechanism is arranged on the first transferring mechanism. The frame is used for carrying the transparent film, arranged on the first transferring mechanism so as to be hung above the base, the frame has a window allowing a surface of the transparent film carrying the colorful chips to face the circuit board, and the colorful chips is arranged in an area corresponding to inside of the window. The color identification module is hung above the frame The punching mechanism is arranged on the second transferring mechanism and hung over the window.

In one embodiment of this disclosure, the color identification module is arranged on the second transferring mechanism and hung over the window.

In one embodiment of this disclosure, the color identification module is driven by the second transferring mechanism and moveable in an area corresponding to inside of the window.

In one embodiment of this disclosure, the surface mount device for colorful chips further has a calibration assembly arranged on the base, and the calibration assembly has a higher reflectance calibration piece and a lower reflectance calibration piece.

In one embodiment of this disclosure, the surface mount device for colorful chips further has a third transferring mechanism, the third transferring mechanism is arranged on the base, and the calibration assembly is arranged on the third transferring mechanism. When the color identification module downward projects into the window, the calibration assembly is moved into a downward projection area of the window by the third transferring mechanism, and the calibration assembly is recognized by the color identification module through the window.

In one embodiment of this disclosure, the calibration assembly is directly arranged on the base. When the frame is moved by the first transferring mechanism to a position over the calibration assembly and the color identification module is moved by the second transferring mechanism to position the window between the color identification module, the calibration assembly, and the calibration assembly is recognized by the color identification module the through the window.

This disclosure is directed to a colorful chips surface mount method has steps of: providing a circuit board and a transparent film carrying a plurality of colorful chips, the circuit board has a mount surface, the mount surface defined with a plurality of mount positions corresponding to the colorful chips, and disposing one surface on the transparent film carrying the colorful chips toward the mount surface of the circuit board; providing a color identification module, recognizing positions of the colorful chips on the transparent film by the color identification module; providing a punching mechanism, disposing the punching mechanism corresponding to another surface on the transparent film opposite to the colorful chips; and moving the transparent film to correspondingly align one of the colorful chips on the transparent film to one of the mount positions on the circuit board, moving the punching mechanism to align the mount position, pressing the transparent film by the punching mechanism to transfer the colorful chip to the mount position, and respectively processing the colorful chips in sequence.

In one embodiment of this disclosure, the colorful chips have a plurality of red chips, and the steps have: disposing a higher reflectance calibration piece as a background of the red chips when recognizing positions of the red chips on the transparent film by the color identification module.

In one embodiment of this disclosure, the colorful chips have a plurality of green chips, and steps have: disposing a lower reflectance calibration piece as a background of the green chips when recognizing positions of the green chips on the transparent film by the color identification module.

In one embodiment of this disclosure, the colorful chips have a plurality of blue chips, and the steps have: disposing a lower reflectance calibration piece as a background of the blue chips when recognizing positions of the blue chips on the transparent film by the color identification module.

According to the surface mount device for colorful chips and the colorful chips surface mount method of this disclosure, the position of the colorful chip may be recognized by the color identification module and then aligned to the mount position by the first transferring mechanism and the second transferring mechanism, so that the colorful chips may be rapidly mounted via the punching mechanism.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing the surface mount device for colorful chips according to one embodiment of this disclosure.

FIGS. 2 to 4 are perspective views showing an operation of the surface mount device for colorful chips according to the embodiment of this disclosure.

FIGS. 5 to 7 are perspective views showing an operation of the punching mechanism of the surface mount device for colorful chips according to the embodiment of this disclosure.

FIG. 8 is a perspective view showing the colorful chips mounted as a product.

FIGS. 9 and 10 are perspective view showing the surface mount device for colorful chips according to another embodiment of this disclosure.

FIG. 11 is a flow chart of the surface mount method for colorful chips according to this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

It should be understood that the orientations or positional relationships in this disclosure which are indicated by the terms such as “front side”, “rear side”, “left side”, “right side”, “front end”, “rear end”, “end”, “vertical”, “horizontal”, “vertical”, “top” and “bottom” are based on the orientations or positional relationships as shown in the drawings. These are only used for describing this disclosure and simplifying the description rather than indicating or implying that the device or element have a specific orientation or be constructed and operated in a specific orientation, and it should not be considered as limitations of the scopes of this disclosure.

The terms used herein without additional definition such as “substantially” and “approximately” are used to describe and illustrate small changes. When used in an event or situation, the term may include the precise moment at which the event or situation occurs, and a close approximation to moment the event or situation occurs. For example, when combined with a numerical value, the term may include a range of variation less than or equal to ±10% of the numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Detailed descriptions and technical contents of this disclosure is described in the flowing paragraph with reference to the drawings. However, the drawings are attached only for illustration and are not intended to limit this disclosure.

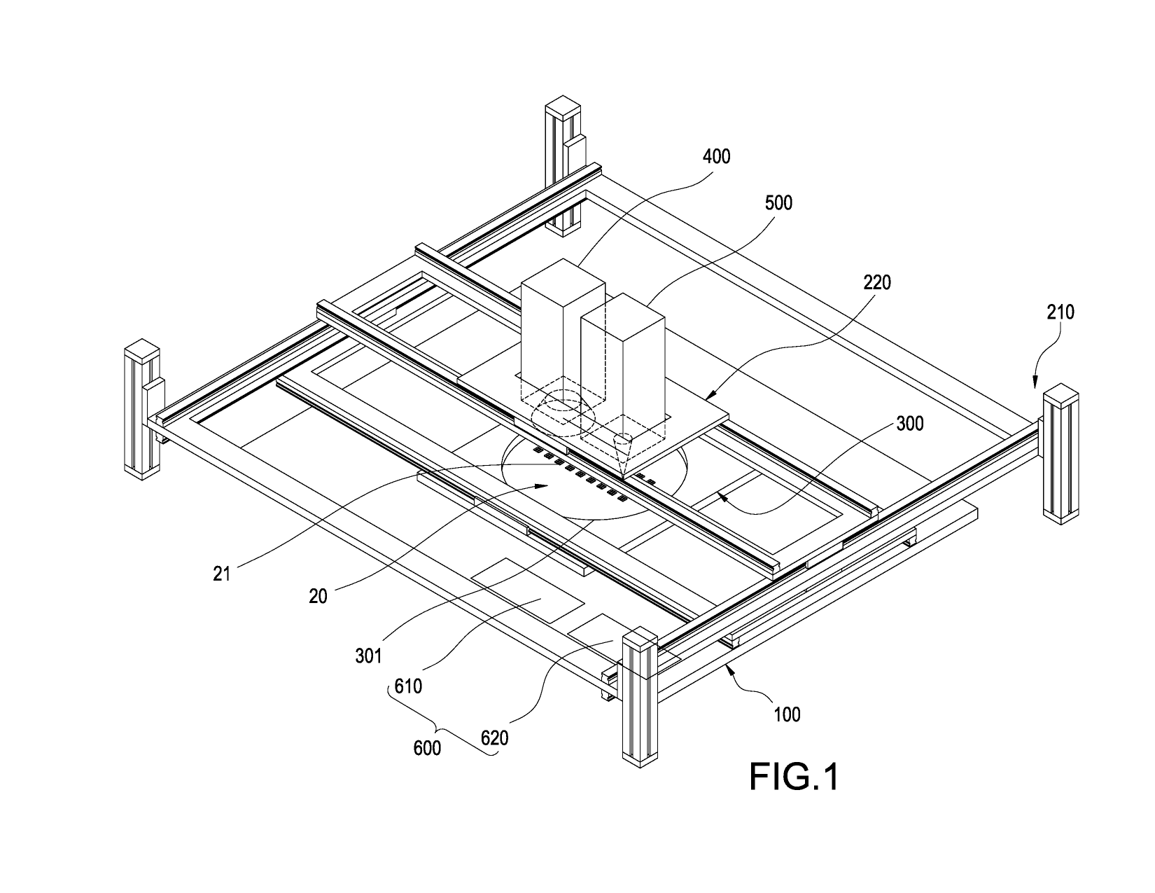

According to FIG. 1, one embodiment of this disclosure provides a surface mount device for colorful chips which is used for transferring a plurality of colorful chips 21 carried on a transparent film 20 onto a circuit board 10. According to this embodiment, the surface mount device for colorful chips has a base 100, a first transferring mechanism 210, a second transferring mechanism 220, a frame 300, a color identification module 400 and a punching mechanism 500.

The base 100 is used for carrying the circuit board 10, and the base 100 of this disclosure should not be limited to specific types. Specifically, the base 100 has an operation plane defined on a top thereof. The circuit board 10 has a mount surface 11, and a plurality of circuits are disposed on the mount surface 11 so as to define a plurality of mount positions 12, the circuit board 10 is laid on the operation plane and the mount surface 11 is disposed upward.

The first transferring mechanism 210 is arranged on the base 100, and the second transferring mechanism 220 is arranged on the first transferring mechanism 210, so that the second transferring mechanism 220 may be moved by the first transferring mechanism 210 along a plane parallel to the operation plane.

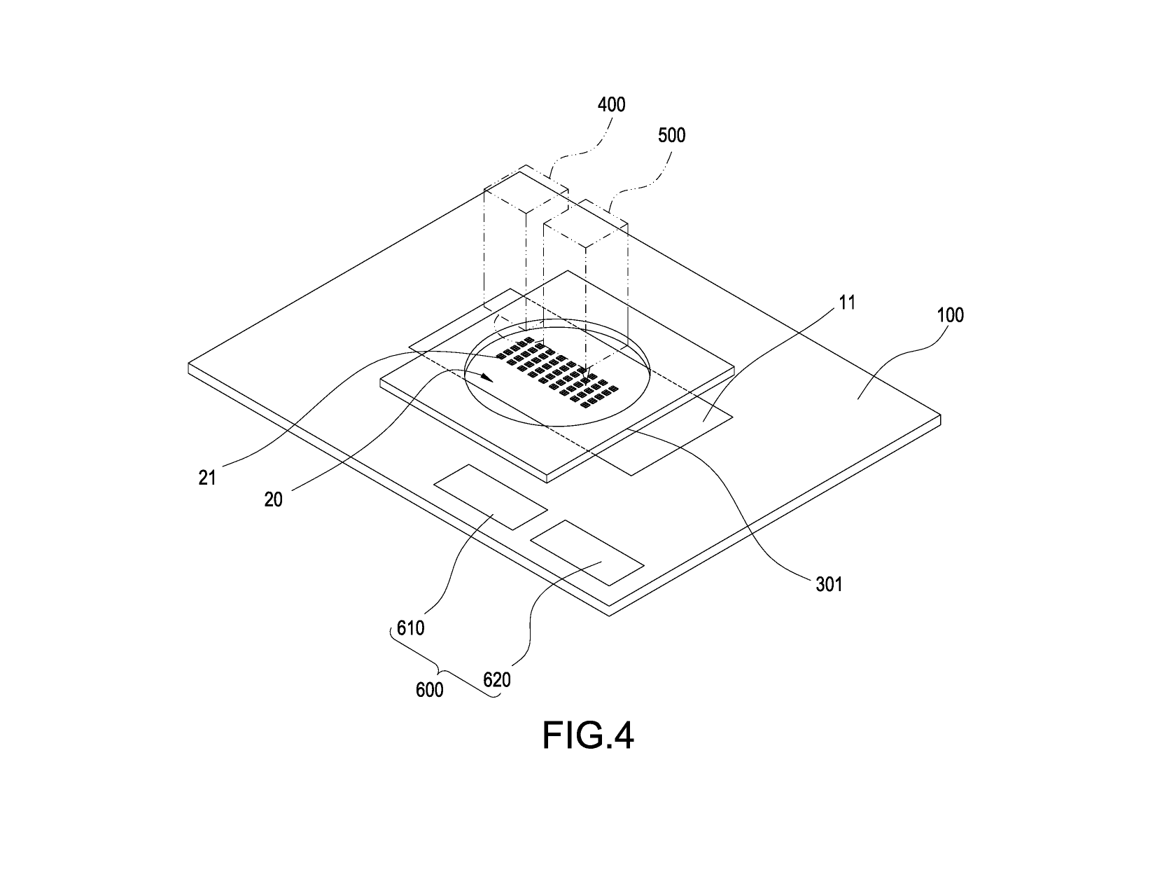

According to FIGS. 1 and 4, the frame 300 is arranged on the first transferring mechanism 210 and hung above the base 100, and the frame 300 may be moved by the first transferring mechanism 210 along a plane parallel to the operation plane. The frame 300 is used for carrying the transparent film 20, the frame 300 has a window 301, one surface of the transparent film 20 carrying the colorful chips 21 is disposed to face the circuit board 10, and the colorful chips 21 are disposed in an area corresponding to inside of the window 301.

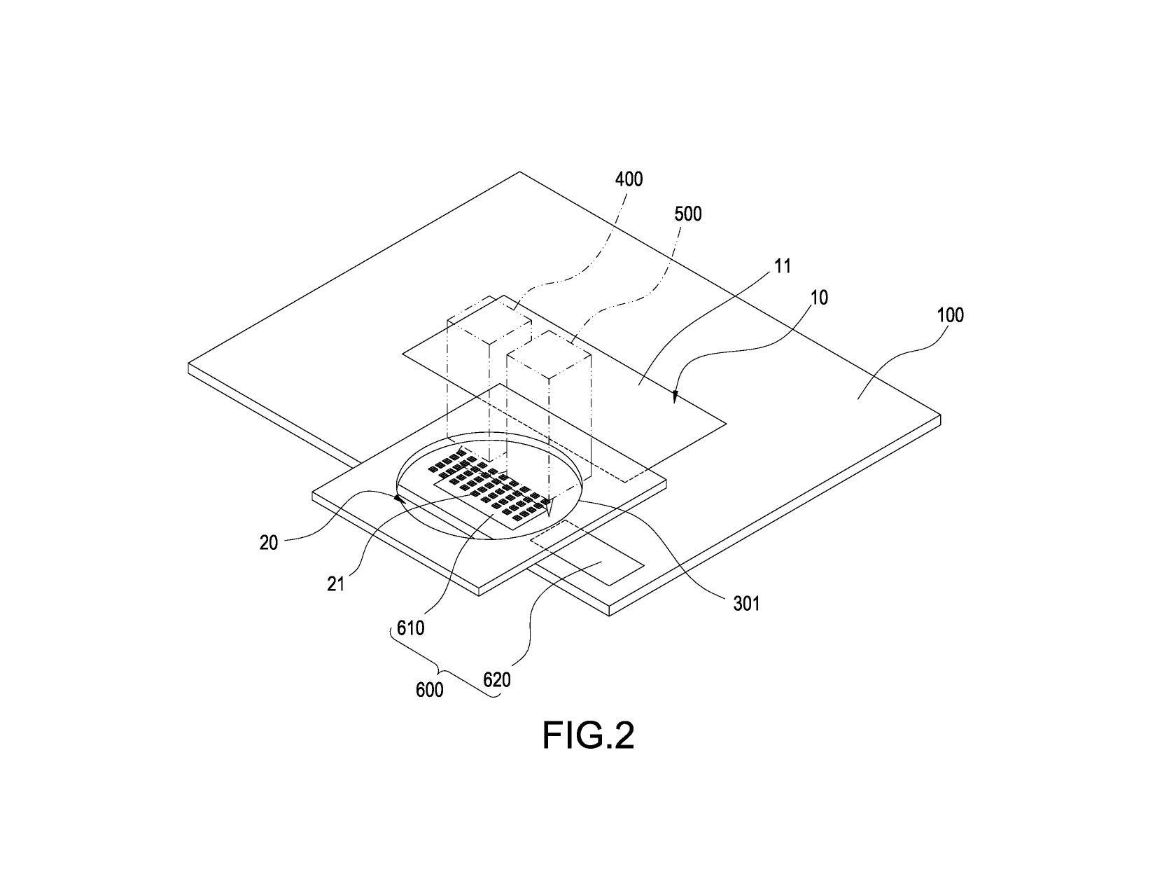

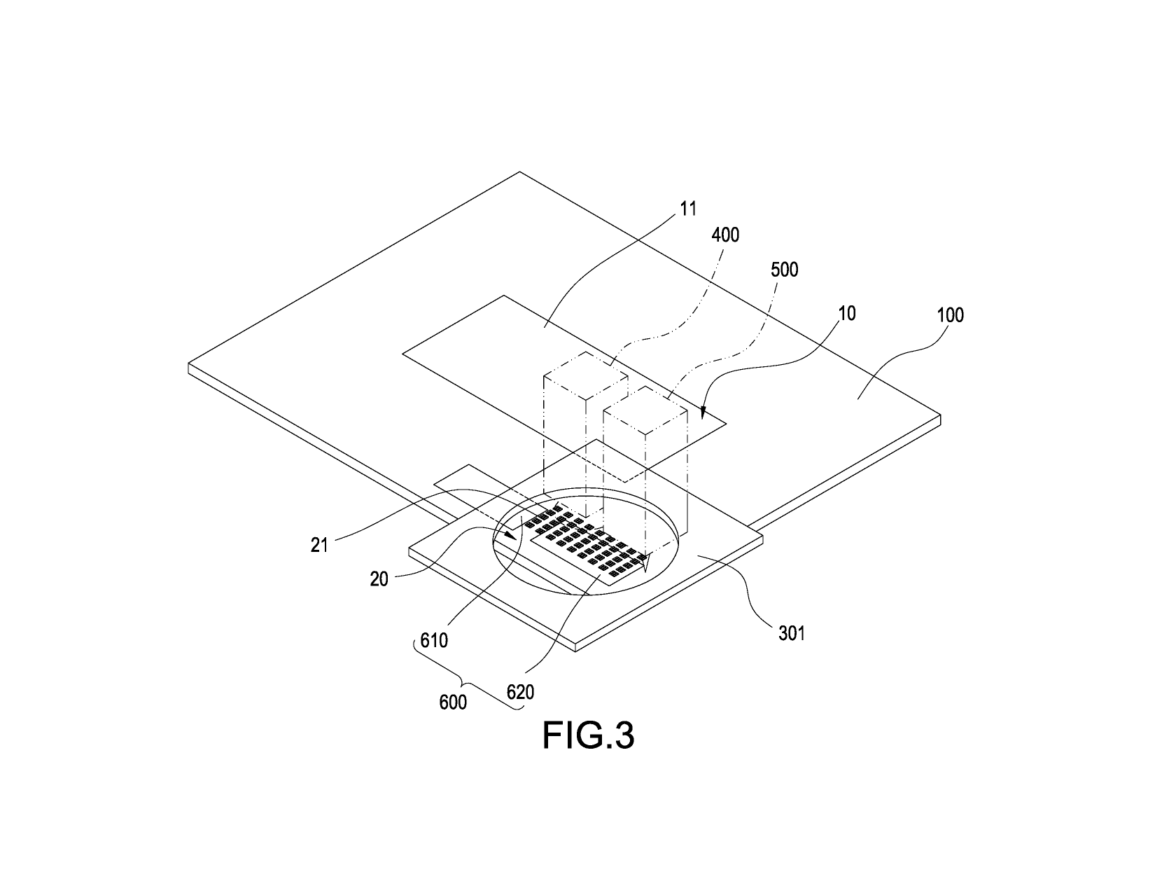

According to FIGS. 1 to 4, the color identification module 400 is hung above the frame 300. According to this embodiment, the color identification module 400 is arranged on the second transferring mechanism 220 and hung over the window 301. Accordingly, the color identification module 400 may be moved by the second transferring mechanism 220, and at least a portion of a downward projection area of the color identification module 400 is in the window 301.

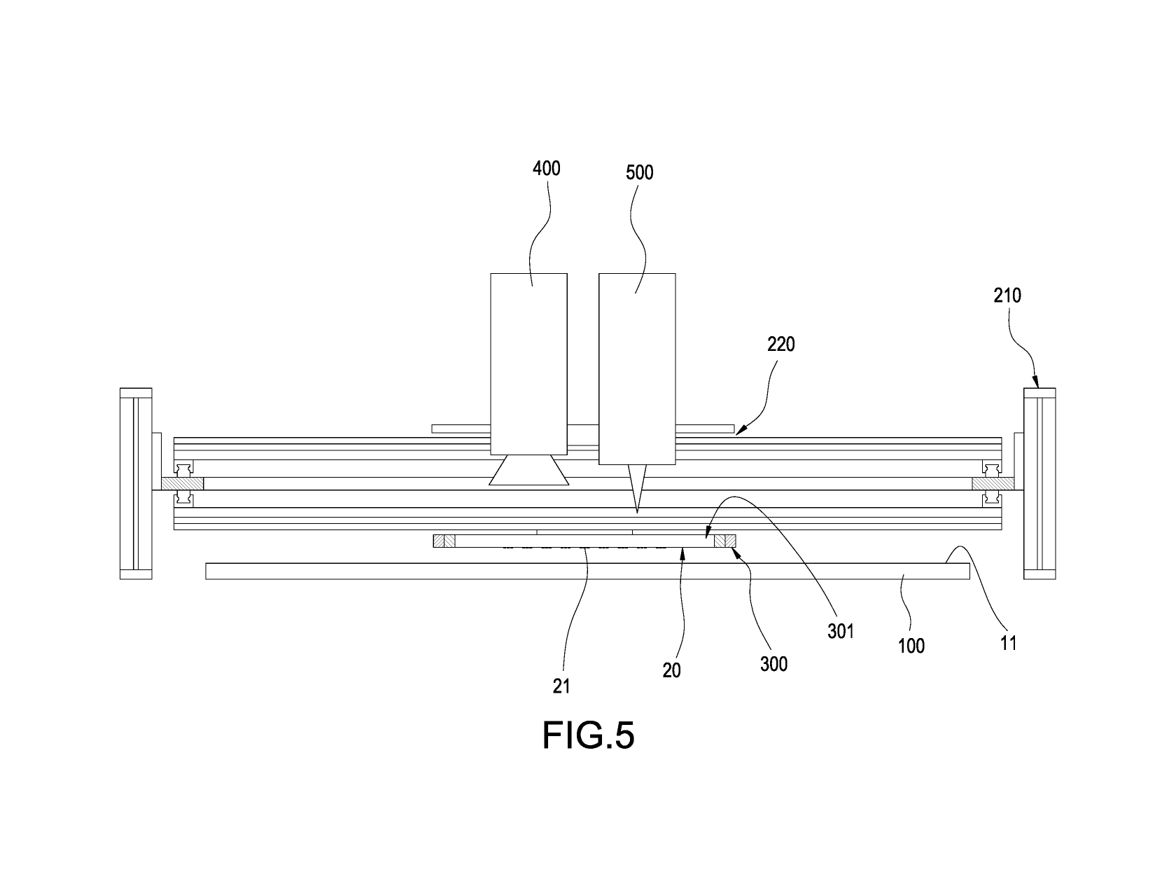

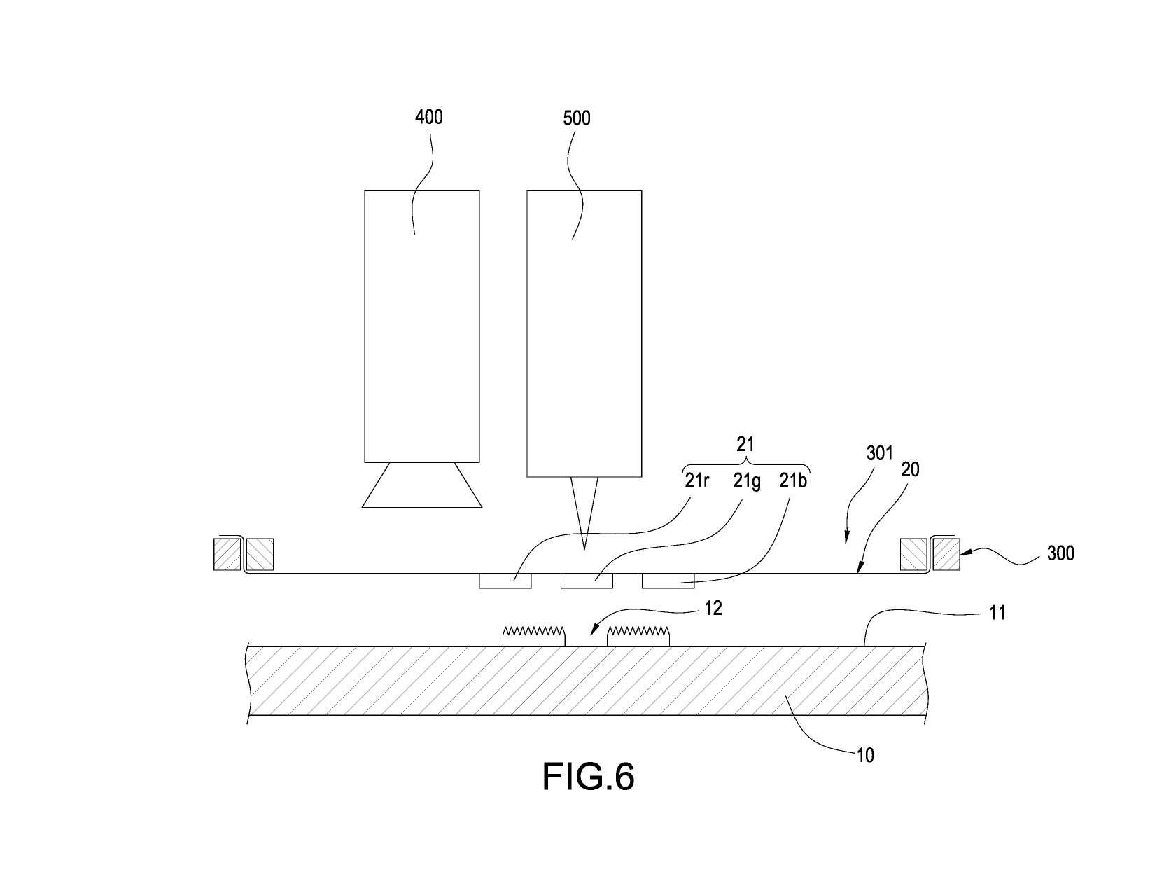

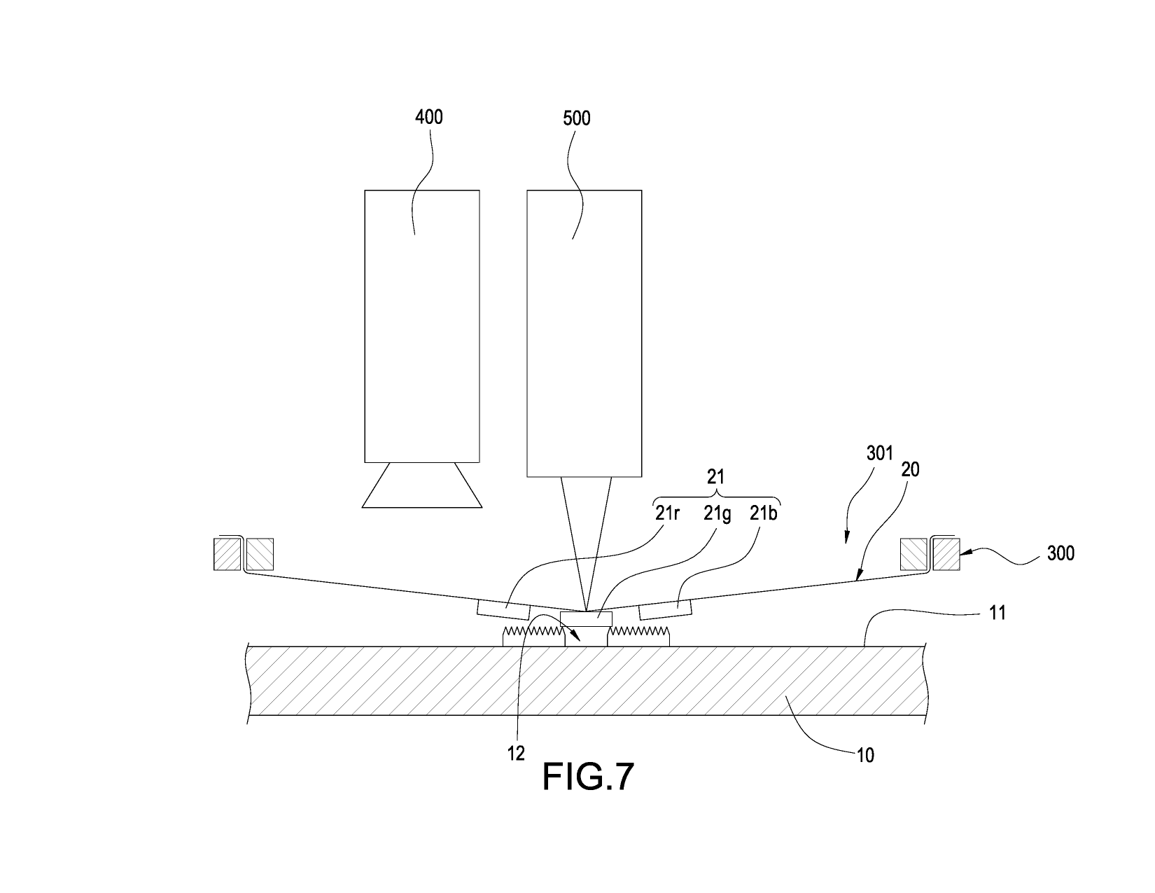

According to FIGS. 1 and 5, the punching mechanism 500 is arranged on the second transferring mechanism 220 and hung over the window 301. According to FIGS. 6 and 7, in general, the punching mechanism 500 has a pin disposed downward and an actuator for moving the pin up and down. Specifically, the plurality of colorful chips 21 have at least one color of a plurality of red chips 21r, a plurality of green chips 21g and a plurality of blue chip 21b. The colorful chips 21 may be disposed together on one transparent film 20 or disposed on a plurality of transparent films 20 respectively according to color.

According to this embodiment as shown in FIGS. 1 to 4, the surface mount device for colorful chips of this disclosure further has a calibration assembly 600, the calibration assembly 600 is directly fixed on the operation plane of the base 100. The calibration assembly 600 has a higher reflectance calibration piece 610 and a lower reflectance calibration piece 620, the higher reflectance calibration piece 610 is a light colored such as white or metallic, the lower reflectance calibration piece 620 is dark such as black. The base 100 may be made of metal, so that a portion of the operation plane may be defined as the higher reflectance calibration piece 610.

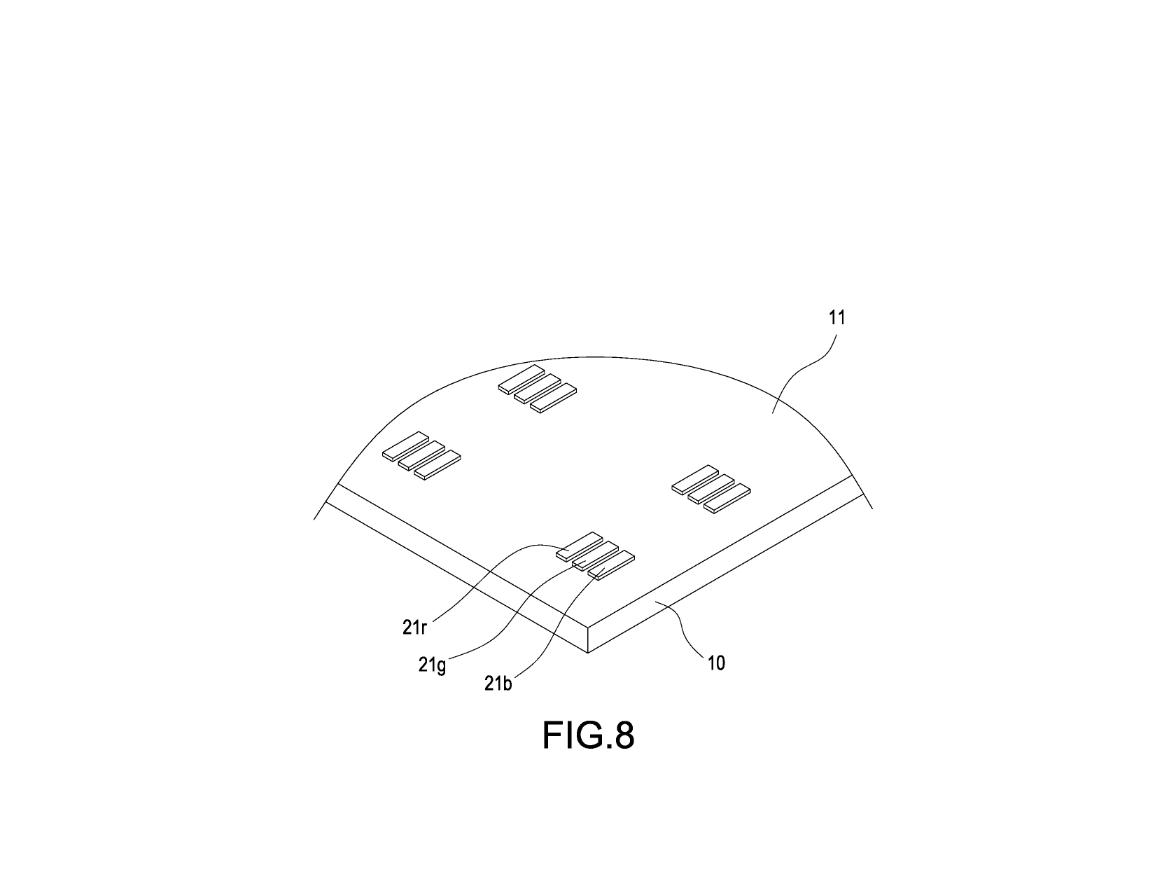

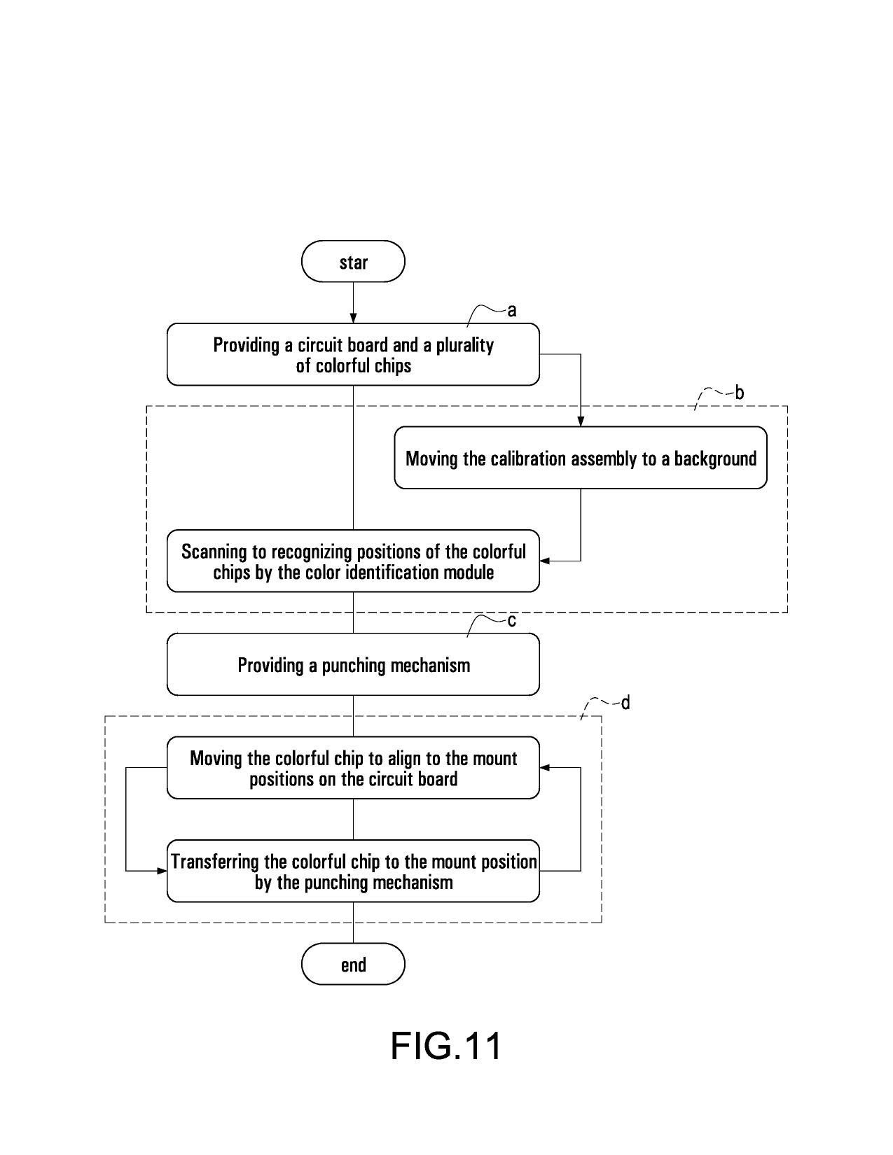

According to this embodiment as shown in FIGS. 1 to 8 and 11, a colorful chips surface mount method of this disclosure is operated via the colorful chips surface mount device mentioned above. The colorful chips surface mount method of this disclosure has steps described in following paragraphs.

In step a, a circuit board 10 and a transparent film 20 carrying a plurality of colorful chips 21 as the embodiment mentioned above are firstly provided, and one surface of the transparent film 20 where the colorful chips 21 are located is disposed to face the mount surface 11 of the circuit board 10.

In step b following step a, a color identification module 400 as the embodiment mentioned above is provided. The color identification module 400, the frame 300 and the calibration assembly 600 are moved relative to each other so that the color identification module 400, the window 301 and the calibration assembly 600 are disposed sequentially from up to down and aligned to each other. According to this embodiment, the frame 300 and the second transferring mechanism 220 are moved by the first transferring mechanism 210 to positions over the calibration assembly 600, so that the calibration assembly 600 is in a downward projection area of the window 301. Then the color identification module 400 may be moved by the second transferring mechanism 220 if required, so that the color identification module 400, the window 301 and the calibration assembly 600 are disposed sequentially from up to down and aligned to each other. Accordingly, the color identification module 400 may recognize the calibration assembly 600 through the window 301 when the color identification module 400 is recognizing the colorful chips 21 in the window 301, namely the color identification module 400 may recognize the colorful chips 21 in front of the calibration assembly 600 as a background. Specifically, the red chips 21r with a lower light reflectance may be highlighted in front of the higher reflectance calibration piece 610 as a background, so that the color identification module 400 may recognize positions of the red chips 21r more easily. Furthermore, the green chips 21g and the blue chips 21b with a higher light reflectance may be highlighted in front of the lower reflectance calibration piece 620 as a background, so that the color identification module 400 may recognize positions of the green chips 21g and the blue chips 21b more easily.

Specifically, the frame 300 may be moved by the first transferring mechanism 210 to a position over the calibration assembly 600, the color identification module 400 may be moved by the second transferring mechanism 220 to position the window 301 between the color identification module 400 and the calibration assembly 600, and the color identification module 400 may recognize the calibration assembly 600 through the window 301.

In step c following step b, a punching mechanism 500 as the embodiment mentioned above is firstly provided, and the punching mechanism 500 is disposed corresponding to another surface on the transparent film 20 opposite to the colorful chips 21.

In step d following step c, the transparent film 20 is moved to align one of the colorful chips 21 on the transparent film 20 to the mount position 12 on the circuit board 10 correspondingly, the punching mechanism 500 is moved to align the pin thereof to the mount position 12, and the transparent film 20 is pressed by the punching mechanism 500 to transfer the colorful chips 21 to the mount position 12, and this step respectively processes the colorful chips in sequence.

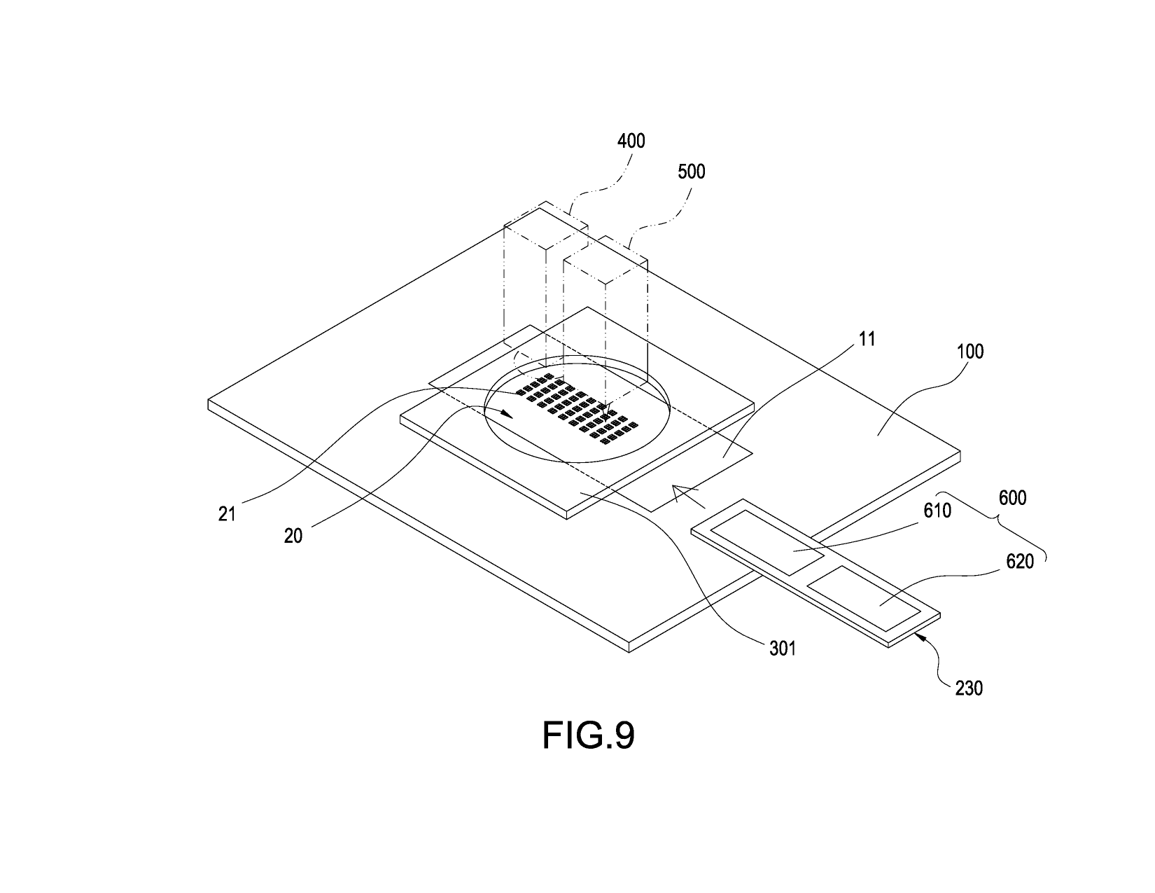

Specifically, the positions of the colorful chips 21 are recognized and then the frame 300 may be moved by the first transferring mechanism 210 to position one of the colorful chips 21 correspondingly over one of the mount positions 12. Furthermore, the punching mechanism 500 is positioned by the first transferring mechanism 210 over the mount position 12 mentioned above and then pressed down to mount the colorful chips 21 mentioned above correspondingly to the mount position 12 on the circuit board 10 as shown in FIG. 9.

According to FIGS. 5 to 11, another embodiment of this disclosure provides a surface mount device for colorful chips used for mounting a plurality of colorful chips 21 carried on a transparent film 20 to a circuit board 10. According to FIGS. 5 to 8, in this embodiment, the surface mount device for colorful chips has a base 100, a first translation mechanism 210, a second translation mechanisms 220, a frame 300, a color identification module 400 and a punching mechanism 500. Specifically, the plurality of colorful chips 21 have at least one color of a plurality of red chips 21r, a plurality of green chips 21g and a plurality of blue chip 21b. The colorful chips 21 may be disposed together on one transparent film 20 or disposed on a plurality of transparent films 20 respectively according to color.

The base 100 is used for carrying the circuit board 10, and the base 100 of this disclosure should not be limited to specific types. Specifically, the base 100 has an operation plane defined on a top thereof. The circuit board 10 has a mount surface 11, and a plurality of mount positions 12 defined on the mount surface 11, the circuit board 10 is laid on the operation plane and the mount surface 11 is disposed upward.

The first transferring mechanism 210 is arranged on the base 100, and the second transferring mechanism 220 is arranged on the first transferring mechanism 210, so that the second transferring mechanism 220 may be moved by the first transferring mechanism 210 along a plane parallel to the operation plane.

The frame 300 is arranged on the first transferring mechanism 210 and hung above the base 100, and the frame 300 may be moved by the first transferring mechanism 210 along a plane parallel to the operation plane. The frame 300 is used for carrying the transparent film 20, the frame 300 has a window 301, one surface of the transparent film 20 carrying the colorful chips 21 is disposed to face the circuit board 10, and the colorful chips 21 are disposed in an area corresponding to inside of the window 301.

The color identification module 400 is hung above the frame 300. According to this embodiment, the color identification module 400 is arranged on the second transferring mechanism 220 and hung over the window 301. Accordingly, the color identification module 400 may be moved by the second transferring mechanism 220, and at least a portion of a downward projection area of the color identification module 400 is in the window 301.

In general, the punching mechanism 500 has a pin disposed downward and an actuator for moving the pin up and down. In general, the punching mechanism 500 has a pin disposed downward and an actuator for moving the pin up and down.

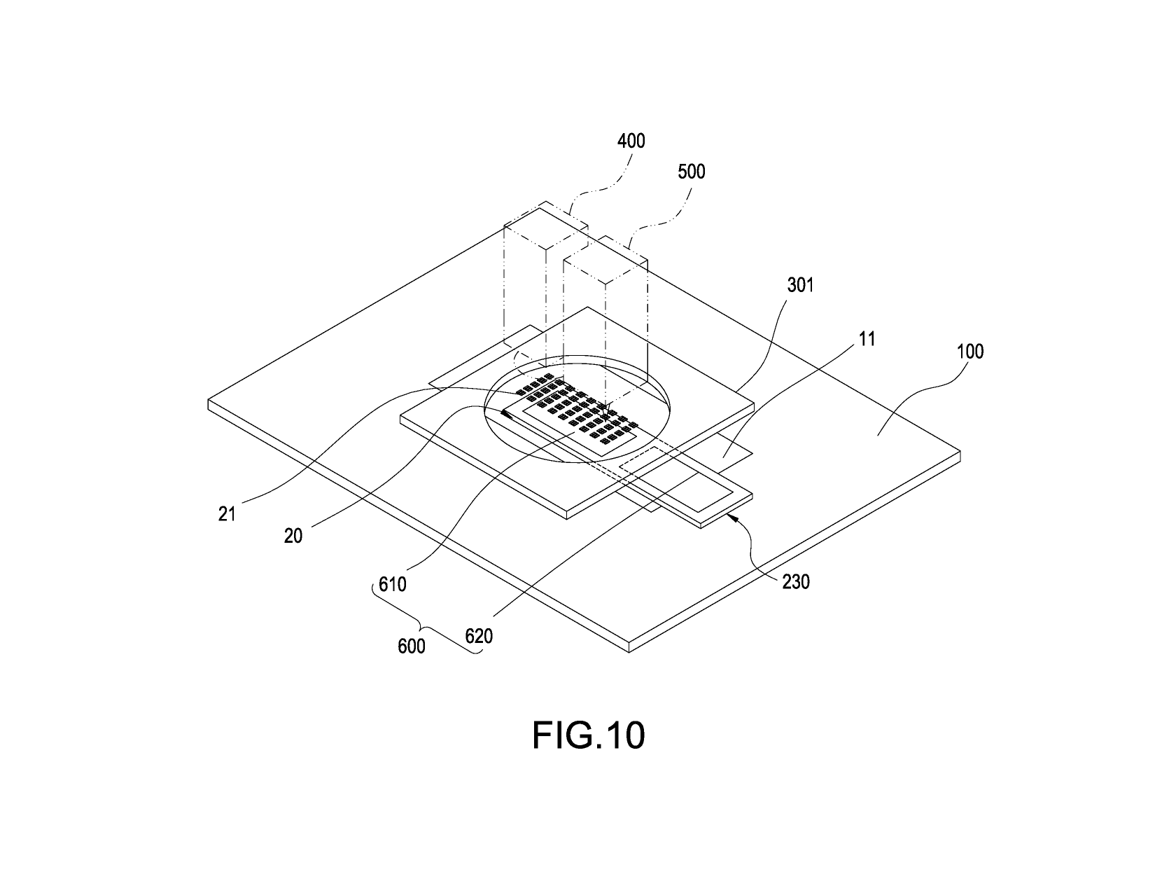

According to FIGS. 9 and 10, this embodiment is different from the previous embodiment in that the surface mount device for colorful chips of this disclosure further has a calibration assembly 600, the calibration assembly 600 is arranged on the base 100 and moveable. Specifically, the surface mount device for colorful chips further has a third transferring mechanism 230, the third transferring mechanism 230 is arranged on the base 100, the calibration assembly 600 is arranged on the third transferring mechanism 230 and may be moved by the third transferring mechanism 230. The calibration assembly 600 has a higher reflectance calibration piece 610 and a lower reflectance calibration piece 620, the higher reflectance calibration piece 610 has a light color such as white or metallic, the lower reflectance calibration piece 620 is dark such as black. The base 100 may be made of metal, so that a portion of the operation plane may be defined as the higher reflectance calibration piece 610.

According to this embodiment, the colorful chips surface mount method of this disclosure is operated by the surface mount device for colorful chips mentioned above so as to mount the colorful chips 21. The colorful chips surface mount method according to this disclosure has steps described following.

In step a, a circuit board 10 and a transparent film 20 carrying a plurality of colorful chips 21 as the embodiment mentioned above are firstly provided, and one surface of the transparent film 20 where the colorful chips 21 are located is disposed to face the mount surface 11 of the circuit board 10.

In step b following step a, a color identification module 400 as the embodiment mentioned above is provided, and positions of the colorful chips 21 carried on the transparent film 20 are recognized by the color identification module 400. Specifically, the color identification module 400, the frame 300 and the calibration assembly 600 are moved relative to each other so that the color identification module 400, the window 301 and the calibration assembly 600 are disposed sequentially from up to down and aligned to each other. According to this embodiment, calibration assembly 600 are moved by the third transferring mechanism 230 to a position in a downward projection area of the window 301. Accordingly, the color identification module 400 may recognize the calibration assembly 600 through the window 301 when the color identification module 400 is recognizing the colorful chips 21 in the window 301, namely the color identification module 400 may recognize the colorful chips 21 in front of the calibration assembly 600 as a background. Specifically, the red chips 21r with a lower light reflectance may be highlighted in front of the higher reflectance calibration piece 610 as a background, so that the color identification module 400 may recognize positions of the red chips 21r more easily. Furthermore, the green chips 21g and the blue chips 21b with a higher light reflectance may be highlighted in front of the lower reflectance calibration piece 620 as a background, so that the color identification module 400 may recognize positions of the green chips 21g and the blue chips 21b more easily.

In step c following step b, a punching mechanism 500 as the embodiment mentioned above are firstly provided, and the punching mechanism 500 is disposed corresponding to another surface on the transparent film 20 opposite to the colorful chips 21.

In step d following step c, the transparent film 20 is moved to align one of the colorful chips 21 on the transparent film 20 to the mount position 12 on the circuit board 10 correspondingly, the punching mechanism 500 is moved to align the pin thereof to the mount position 12, and the transparent film 20 is pressed by the punching mechanism 500 to transfer the colorful chips 21 to the mount position 12, and this step respectively processes the colorful chips in sequence.

Specifically, the positions of the colorful chips 21 are recognized and then the frame 300 may be moved by the first transferring mechanism 210 to position one of the colorful chips 21 correspondingly over one of the mount positions 12. Furthermore, the punching mechanism 500 is positioned by the first transferring mechanism 210 over the mount position 12 mentioned above and then pressed down to mount the colorful chips 21 mentioned above correspondingly to the mount position 12 on the circuit board 10 as shown in FIG. 9.

According to the surface mount device for colorful chips and the colorful chips surface mount method of this disclosure, the position of the colorful chip 21 may be recognized by the color identification module 400 and then aligned to the mount position 12 by the first transferring mechanism 210 and the second transferring mechanism 220, so that the colorful chips 21 may be rapidly mounted via the punching mechanism 500.

While this disclosure has been described by means of specific embodiments, numerous modifications and variations could be made thereto by those skilled in the art without departing from the scope and spirit of this disclosure set forth in the claims.

What is claimed is:

1. A surface mount device for colorful chips for mounting a plurality of colorful chips carried on a transparent film on to a circuit board, the surface mount device for colorful chips comprising:
a base for carrying the circuit board;
a first transferring mechanism, arranged on the base;
a second transferring mechanism, arranged on the first transferring mechanism;
a frame for carrying the transparent film, arranged on the first transferring mechanism so as to be hung above the base, the frame comprising a window allowing a surface of the transparent film carrying the colorful chips to face the circuit board and the colorful chips arranged in an area corresponding to inside of the window;
a color identification module, hung above the frame; and
a punching mechanism, arranged on the second transferring mechanism and hung over the window.

2. The surface mount device for colorful chips according to claim 1, wherein the color identification module is arranged on the second transferring mechanism and hung over the window.

3. The surface mount device for colorful chips according to claim 2, wherein the color identification module is driven by the second transferring mechanism and moveable in an area corresponding to inside of the window.

4. The surface mount device for colorful chips according to claim 1, further comprising a calibration assembly arranged on the base, and the calibration assembly comprising a higher reflectance calibration piece and a lower reflectance calibration piece.

5. The surface mount device for colorful chips according to claim 4, further comprising a third transferring mechanism, the third transferring mechanism arranged on the base, and the calibration assembly arranged on the third transferring mechanism.

6. The surface mount device for colorful chips according to claim 5, wherein when the color identification module downward projects into the window, the calibration assembly is moved into a downward projection area of the window by the third transferring mechanism, and the calibration assembly is recognized by the color identification module through the window.

7. The surface mount device for colorful chips according to claim 4, wherein the calibration assembly is directly arranged on the base.

8. The surface mount device for colorful chips according to claim 7, wherein when the frame is moved by the first transferring mechanism to a position over the calibration assembly and the color identification module is moved by the second transferring mechanism to position the window between the color identification module, the calibration assembly, and the calibration assembly is recognized by the color identification module through the window.

9. A colorful chips surface mount method, comprising:
a) providing a circuit board and a transparent film carrying a plurality of colorful chips, the circuit board comprising a mount surface, the mount surface defined with a plurality of mount positions corresponding to the colorful chips, and disposing one surface on the transparent film carrying the colorful chips toward the mount surface of the circuit board;
b) providing a color identification module, recognizing positions of the colorful chips on the transparent film by the color identification module;
c) providing a punching mechanism, disposing the punching mechanism corresponding to another surface on the transparent film opposite to the colorful chips; and
d) moving the transparent film to correspondingly align one of the colorful chips on the transparent film to one of the mount positions on the circuit board, moving the punching mechanism to align the mount position, pressing the transparent film by the punching mechanism to transfer the colorful chip to the mount position, and respectively processing the colorful chips in sequence.

10. The surface mount method for colorful chips according to claim 9, wherein the colorful chips comprise a plurality of red chips, and step b comprises: disposing a higher reflectance calibration piece as a background of the red chips when recognizing positions of the red chips on the transparent film by the color identification module.

11. The surface mount method for colorful chips according to claim 9, wherein the colorful chips comprise a plurality of green chips, and step b comprises: disposing a lower reflectance calibration piece as a background of the green chips when recognizing positions of the green chips on the transparent film by the color identification module.

12. The surface mount method for colorful chips according to claim 9, wherein the colorful chips comprise a plurality of blue chips, and step b comprises: disposing a lower reflectance calibration piece as a background of the blue chips when recognizing positions of the blue chips on the transparent film by the color identification module.
